(19) United States
(12) Patent Application Publication
(10) Pub. No.: US 2016/0128183 A1
(43) Pub. Date: May 5, 2016

(54) WIRING BOARD

(71) Applicant: KYOCERA Circuit Solutions, Inc., Kyoto (JP)

(72) Inventor: Keisaku MATSUMOTO, Ritto-shi (JP)

(73) Assignee: KYOCERA Circuit Solutions, Inc., Kyoto (JP)

(21) Appl. No.: 14/918,618

(22) Filed: Oct. 21, 2015

(30) Foreign Application Priority Data
Oct. 30, 2014 (JP) 2014-221171

(51) Int. Cl. H05K 1/02

(52) U.S. Cl. CPC H05K 1/0296; H05K 1/0218

(57) ABSTRACT

The wiring board of the present invention includes an insulating layer, a strip-shaped wiring conductor for signals disposed on a main surface of the insulating layer, and a plain conductor for grounding or power disposed on the main surface of the insulating layer; and the thickness of the plane conductor is larger than the thickness of the strip-shaped wiring conductor. In the wiring board of the present invention, the thickness of the plane conductor is preferably 1 to 15 μm larger than the thickness of the strip-shaped wiring conductor. The strip-shaped wiring conductor has a thickness of preferably 3 to 10 μm, and the plane conductor has a thickness of preferably 5 to 15 μm.

### BACKGROUND OF THE INVENTION

1. TECHNICAL FIELD

The present invention relates to a wiring board for mounting a semiconductor element such as a semiconductor integrated circuit device.

2. BACKGROUND

FIG. 3 shows a conventional wiring board B for mounting a semiconductor element such as a semiconductor integrated circuit device. The wiring board B includes an insulating layer 11, a conductor layer 12, and a solder resist layer 13. For example, this wiring board is described in Japanese Unexamined Patent Application Publication No. 2014-130974.

A plurality of through-holes 14 are formed in the insulating layer 11. A part of the conductor layer 12 is deposited on the upper and lower surfaces of the insulating layer 11 and in the through-holes 14. The conductor layer 12 includes a plurality of strip-shaped wiring conductors 12a for signals where electrical signals are transmitted, and a plurality of plane conductors 12b for grounding or power for the potential supply or the power supply. The solder resist layer 13 is deposited on the upper and lower surfaces of the insulating layer 11. An opening portion 13a exposing a part of the conductor layer 12 as a semiconductor element connection pad 15 is formed in the solder resist layer 13 deposited on the upper surface of the insulating layer 11. An electrode terminal of the semiconductor element is connected to the semiconductor element connection pad 15 via the solder.

An opening portion 13b exposing a part of the conductor layer 12 as an external connection pad 16 is formed in the solder resist layer 13 deposited on the lower surface of the insulating layer 11. A wiring conductor of an external electric circuit board is connected to the external connection pad 16 via the solder.

In recent years, power consumption of the electronic devices represented by portable music players and communications devices is increased due to the higher functionality thereof. Therefore, a power-saving type wiring board is required for the wiring board B to be used for these electronic devices. Thus, it is considered to lower the operating voltage of the semiconductor element for power saving.

However, when the operating voltage is lowered, a malfunction is likely to occur because of the less margin against noise. Adequate power supply is desired to reduce such noise. For this purpose, it is necessary to increase the thickness of the plane conductor 12b. However, the plane conductor 12b and the strip-shaped wiring conductor 12a are formed by the electroplating being simultaneously precipitated on the insulating layer 11, and therefore the strip-shaped wiring conductor 12a also becomes thicker. When the strip-shaped wiring conductor 12a becomes thicker, there is a problem that the wiring of the fine line-and-space cannot be formed, and the board cannot be miniaturized.

### SUMMARY

The present invention provides a small high-density wiring board capable of adequate power supply to a semiconductor element to be mounted, capable of operating a semiconductor element with a low operating voltage stably, and including a fine line-and-space.

The wiring board according to an embodiment of the present invention includes an insulating layer, a strip-shaped wiring conductor for signals disposed on a main surface of the insulating layer, and a plain conductor for grounding or power disposed on the main surface of the insulating layer; and the thickness of the plane conductor is larger than the thickness of the strip-shaped wiring conductor.

According to the wiring board according to the embodiment of the present invention, the thickness of the plane conductor for grounding or power is larger than the thickness of the strip-shaped wiring conductor for signals. Thereby, adequate power supply to the semiconductor element to be mounted is made possible. Therefore, the embodiment of the present invention can provide a small high-density wiring board capable of operating a semiconductor element with a low operating voltage stably, and including a fine line-and-space.

### BRIEF DESCRIPTION OF THE DRAWINGS

FIG. 1 is a schematic cross-sectional view showing a wiring board according to one embodiment of the present invention;

FIG. 2 is a main part enlarged cross-sectional view showing the wiring board according to the one embodiment of the present invention; and

FIG. 3 is a schematic cross-sectional view showing a conventional wiring board.

### DETAILED DESCRIPTION

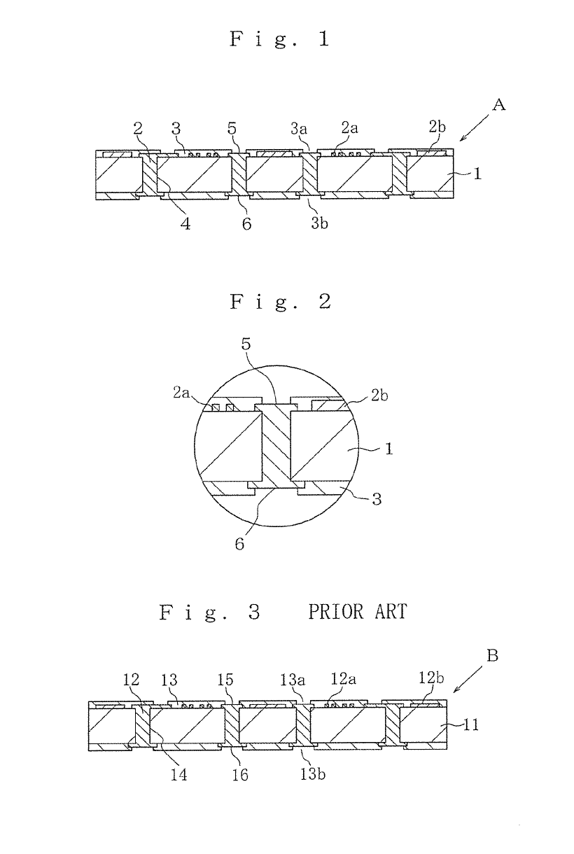

Next, the wiring board according to one embodiment will be described in detail with reference to FIGS. 1 and 2. A schematic cross-sectional view of a wiring board A according to the one embodiment is shown in FIG. 1. The wiring board A includes an insulating layer 1, a conductor layer 2, and a solder resist layer 3.

The insulating layer 1 is, for example, formed of electrically insulating material where the glass cloth in which a glass fiber bundle is woven in the vertical and horizontal directions is impregnated with a thermosetting resin such as an epoxy resin and a bismaleimide triazine resin. The thickness of the insulating layer 1 is preferably about 50 to 800 μm. In the insulating layer 1, a plurality of through-holes 4 penetrating from the upper surface to the lower surface and having a diameter of about 100 to 300 μm are formed. The through-hole 4 is formed by, for example, drilling and laser processing, blast processing, and the like.

The conductor layer 2 is deposited on the upper and lower surfaces of the insulating layer 1 and in the through-holes 4. The conductor layer 2 includes a plurality of strip-shaped wiring conductors 2a for signals where electrical signals are transmitted, and a plurality of plane conductors 2b for grounding or power for the potential supply or the power supply.

As shown in FIG. 2, the thickness of the plane conductor 2b is formed larger than the thickness of the strip-shaped wiring conductor 2a. Preferably, the thickness of the plane conductor 2b is about 1 to 15 μm larger than the thickness of strip-shaped wiring conductor 2a. The thickness of the strip-shaped wiring conductor 2a is, for example, about 3 to 10 μm, preferably about 6 μm, and the width of each wiring is about 2 μm to 10 μm. In addition, the thickness of the plane conductor 2b is, for example, about 5 to 15 μm, preferably about 7 μm to 8 μm.

The electroless copper plating layer and the electrolytic copper plating layer are precipitated on the surface of the insulating layer 1 by, for example, a well-known semi-additive method, whereby the conductor layer 2 is formed. Specifically, the method is as follows. First, the electroless copper plating processing is performed on the surface of the insulating layer 1. After the processing, the surface of the insulating layer 1 is dried, and a pattern is formed by the plating resist. The part not forming a pattern is masked by the plating resist. Then, the electrolytic copper plating processing is performed, whereby a pattern is grown only in a part where the electroless copper plating is exposed. After the electrolytic copper plating processing, the plating resist is peeled off, and the electroless copper plating exposing from the electrolytic copper plating is removed by etching.

So as to precipitate a plane conductor 2b thicker than the thickness of the strip-shaped wiring conductor 2a, for example, when the electrolytic copper plating in the semi-additive method is precipitated, it is sufficient to perform the electrolytic copper plating in a relatively large current density by using a DC power supply. The current density is preferably 3 A/dm² or more. When the electrolytic copper plating is precipitated in a large current density, there is a tendency that the precipitation rate of the part with a large precipitation area is faster than that of the part with a small precipitation area. Therefore, the thickness of the plane conductor 2b can be increased more than the thickness of the strip-shaped wiring conductor 2a. The wiring width of the strip-shaped wiring conductor 2a has a limit in the processing by the semi-additive method, and is at least about 2 μm.

The solder resist layer 3 is formed of an electrically insulating material containing a thermosetting resin such as an epoxy resin and a polyimide resin. The solder resist layer 3 is deposited on the upper and lower surfaces of the insulating layer 1. An opening portion 3a exposing a part of the conductor layer 2 as a semiconductor element connection pad 5 is formed in the solder resist layer 3 deposited on the upper surface of the insulating layer 1. The opening portion 3a has a circular shape usually. The semiconductor element connection pad 5 also has a circular shape depending on the shape of the opening portion 3a. An electrode terminal of the semiconductor element is connected to the semiconductor element connection pad 5 via the solder.

An opening portion 3b exposing a part of the conductor layer 2 as an external connection pad 6 is formed in the solder resist layer 3 deposited on the lower surface of the insulating layer 1. The opening portion 3b has a circular shape usually. The external connection pad 6 also has a circular shape depending on the shape of the opening portion 3b. A wiring conductor of an external electric circuit board is connected to the external connection pad 6 via the solder.

Thus, according to the wiring board according to the one embodiment, the thickness of the plane conductor 2b is formed larger than the thickness of the strip-shaped wiring conductor 2a. Thereby, adequate power supply to the semiconductor element to be mounted is made possible. Therefore, the one embodiment of the present invention can provide a small high-density wiring board capable of operating a semiconductor element with a low operating voltage stably, and including a fine line-and-space.

The present invention is not intended to be limited to the one embodiment described above, and various modifications are possible as long as they are within the scope of the claims. For example, in the wiring board A described above, the insulating layer 1 has a single layer structure. However, the insulating layer may have a structure where a plurality of insulating layers formed of the same or different insulating materials are laminated.

As described above, the opening portion 3a has a circular shape usually. However, the shape of the opening portion 3a is not limited to a circular shape. The opening portion 3a may have a shape such as an elliptical shape and a polygonal shape (a triangular shape, a quadrangular shape, a pentagonal shape, a hexagonal shape, and the like). The semiconductor element connection pad 5 may also have a shape such as an elliptical shape and a polygonal shape depending on the shape of the opening portion 3a.

As described above, the opening 3b has a circular shape usually. However, the shape of the opening portion 3b is not limited to a circular shape. The opening portion 3b may have a shape such as an elliptical shape and a polygonal shape (a triangular shape, a quadrangular shape, a pentagonal shape, a hexagonal shape, and the like). The external connection pad 6 may also have a shape such as an elliptical shape and a polygonal shape depending on the shape of the opening portion 3b.

What is claimed is:

1. A wiring board comprising:
an insulating layer;
a strip-shaped wiring conductor for a signal disposed on a main surface of the insulating layer; and
a plane conductor for grounding or power disposed on the main surface of the insulating layer, wherein the thickness of the plane conductor is larger than the thickness of the strip-shaped wiring conductor.

2. The wiring board according to claim 1, wherein the thickness of the plane conductor is 1 to 15 μm larger than the thickness of the strip-shaped wiring conductor.

3. The wiring board according to claim 1, wherein the strip-shaped wiring conductor has a thickness of 3 to 10 μm.

4. The wiring board according to claim 1, wherein the plane conductor has a thickness of 5 to 15 μm.
